(19) United States
(12) Patent Application Publication
(10) Pub. No.: US 2026/0371631 A1
(43) Pub. Date: Nov. 19, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Kuei-Yu Kao, Hsinchu (TW); Chiung-Yu Cho, Hsinchu County (TW)

(73) Assignee: Taiwan Semiconductor Manufacturing Company, Ltd., Hsinchu (TW)

(21) Appl. No.: 19/208,142

(22) Filed: May 14, 2025

(51) Int. Cl. H10D 30/01; H10D 30/00

(52) U.S. Cl. CPC H10D 30/0191; H10D 30/502

(57) ABSTRACT

A method, includes: providing a semiconductor structure including a plurality of channel structures and a plurality of sacrificial epitaxial layers, a sacrificial gate structure, and gate sidewall spacers formed on sidewalls of the sacrificial gate structure; recessing the semiconductor structure in source and drain regions; removing the sacrificial epitaxial layers; depositing sacrificial refill layer material over the semiconductor structure; selectively etching the sacrificial refill layer material using a plurality of selective removal sequences, wherein each selective removal sequence includes a treatment phase and a removal phase, wherein the treatment phase includes softening an outer portion of the sacrificial refill layer material and the removal phase includes removing the softened outer portion of the sacrificial refill layer material; forming an inner spacer layer at sidewalls of the sacrificial refill layer material; forming source/drain features; and replacing the sacrificial gate structure and the sacrificial refill layer material with a metal gate structure.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart depicting an example method of semiconductor fabrication including fabrication of multi-gate devices, in accordance with some embodiments.

FIGS. 2-3, 4A-4C, 5, 6A-6B, 7-11, and 17-24 are schematic diagrams illustrating an example semiconductor device or structure at various stages of fabrication, in accordance with some embodiments.

FIG. 12 is a flow chart depicting an example method 300 for selectively removing portions of the sacrificial refill layer between adjacent fins, in accordance with some embodiments.

FIGS. 13-16 are schematic diagrams illustrating an example semiconductor device or structure at various stages of fabrication, in accordance with some embodiments.

FIGS. 25-27 are schematic diagrams illustrating an example semiconductor structure that has undergone a process for removing sacrificial refill layers and releasing the nanosheets during fabrication of a GAA device, in accordance with some embodiments.

FIGS. 28-29 are schematic diagrams illustrating an example semiconductor structure after metal gate fabrication operations, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

It should be understood that, although the terms first, second, third etc. may be used herein to describe various elements, components, regions, layers, portions and/or sections, these elements, components, regions, layers, portions, and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

It is to be understood that the phraseology or terminology expressed herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

While the figures illustrate various embodiments of a semiconductor device, additional features may be added in the semiconductor device depicted in the Figures and some of the features described below can be replaced, modified, or eliminated in other embodiments of the semiconductor device.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

The present disclosure is generally related to semiconductor devices and the fabrication thereof, and in some cases to multi-gate devices. Multi-gate devices include those transistors whose gate structures are formed on at least two-sides of a channel region. These multi-gate devices may include an n-type metal-oxide-semiconductor device or a p-type metal-oxide-semiconductor multi-gate device. Specific examples herein may be presented and referred to herein as a type of multi-gate transistor referred to as a gate-all-around field effect transistor (GAAFET). A GAAFET includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Presented herein are embodiments of devices that may have one or more channel regions (e.g., nanosheets) associated with a single, contiguous gate structure. One of ordinary skill may recognize other examples of semiconductor devices that may benefit from aspects of the present disclosure.

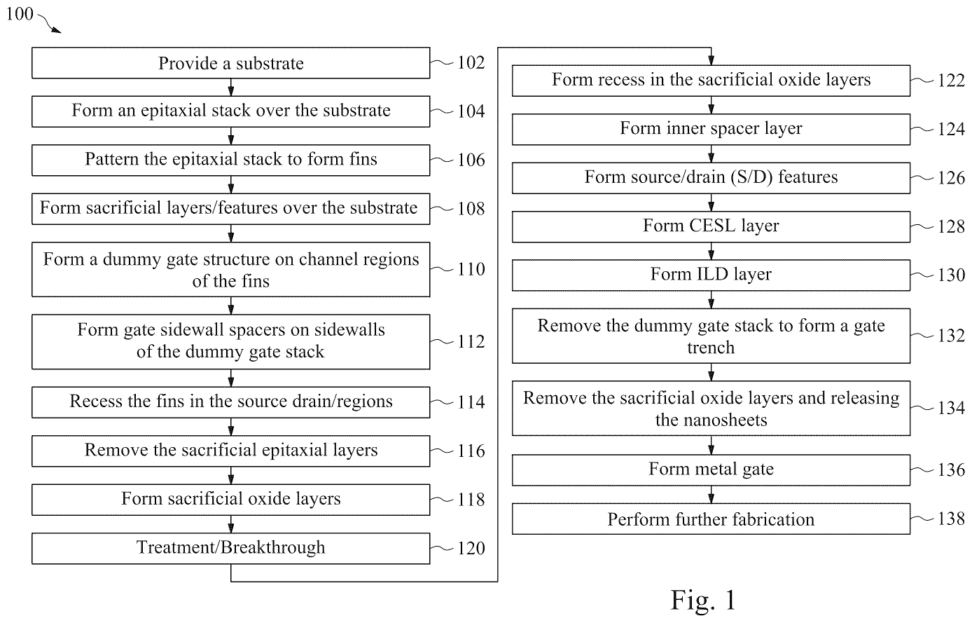

FIG. 1 is a flow chart depicting an example method 100 of semiconductor fabrication including fabrication of multi-gate devices, according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAA device having gate material disposed on four sides of at least one channel member of the device. The channel member may be referred to as “nano structure” or “nanosheet,” which is used herein to designate any material portion with nanoscale, or even microscale dimensions, and having an elongate shape, regardless of the cross-sectional shape of this portion. Thus, the term “nanostructure” or “nanosheet” as used herein designates both circular and substantially circular cross-section elongate material portions, and beam or bar-shaped material portions including for example a cylindrical in shape or substantially rectangular cross-section.

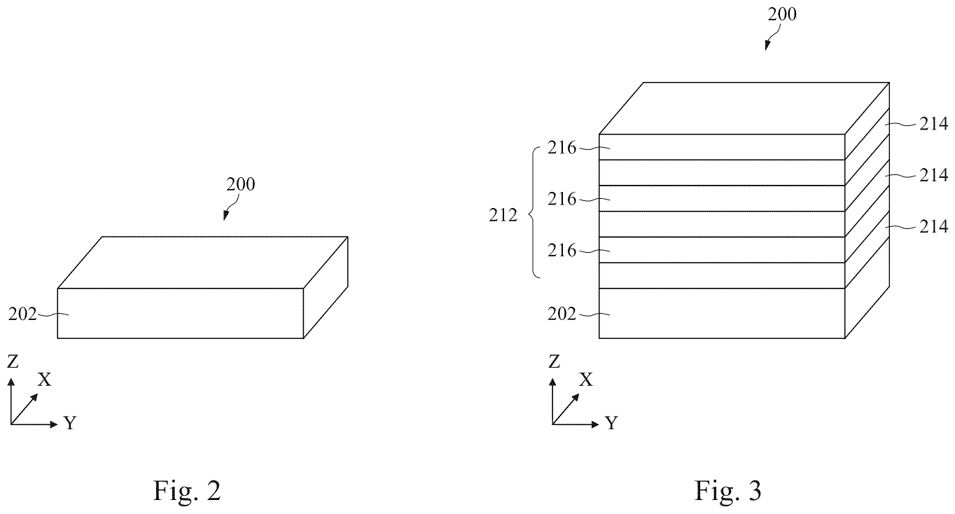

FIG. 1 is described in conjunction with FIGS. 2-3, 4A-4C, 5, 6A-6B, 7-11, and 17-24, which illustrate a semiconductor structure 200 or structure at various stages of fabrication in accordance with some embodiments. In some figures, some reference numbers of components or features illustrated therein may be omitted to avoid obscuring other components or features; this is for ease of depicting the figures. The method 100 is merely an example and is not intended to limit the present disclosure beyond what is explicitly recited in the claims. Additional steps may be provided before, during, and after method 100, and some of the steps described can be moved, replaced, or eliminated for additional embodiments of method 100. Additional features may be added in the semiconductor structure 200 depicted in the figures, and some of the features described below can be replaced, modified, or eliminated in other embodiments.

As with the other method embodiments and exemplary devices discussed herein, it is understood that parts of the semiconductor devices may be fabricated by semiconductor technology process flow, and thus some processes are only briefly described herein. Further, the exemplary semiconductor devices may include various other devices and features, such as other types of devices such as additional transistors, bipolar junction transistors, resistors, capacitors, inductors, dials, fuses, and/or other logic devices, etc., but is simplified for better understanding of concepts of the present disclosure. In some embodiments, exemplary devices include a plurality of semiconductor devices (e.g., transistors), including PFETs, NFETs, etc., which may be interconnected. Moreover, it is noted that the process steps of method 100, include any descriptions given with reference to the figures, as with the remainder of the method and exemplary figures provided in this disclosure, are merely exemplary and are not intended to be limiting beyond what is specifically recited in the claims that follow.

At block 102, the example method 100 includes providing a substrate. Referring to the example of FIG. 2, in an embodiment of block 102, a substrate 202 is provided for forming a semiconductor structure 200. In some embodiments, the substrate 202 may be a semiconductor substrate such as a silicon (Si) substrate. In some embodiments, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. The substrate 202 may include various layers, including conductive or insulating layers formed on a semiconductor substrate. The substrate 202 may include various doping configurations depending on design requirements. For example, different doping profiles (e.g., n wells, p wells) may be formed on the substrate 202 in regions designed for different device types (e.g., n-type field effect transistors (NFET), p-type field effect transistors (PFET)). The suitable doping may include ion implantation of dopants and/or diffusion processes. The substrate 202 has isolation features (e.g., shallow trench isolation (STI) features) interposing the regions providing different device types. Further, the substrate 202 may be strained for performance enhancement, may include a silicon-on-insulator (SOI) structure, and/or have other suitable enhancement features.

At block 104, the example method 100 includes forming an epitaxial stack that includes a plurality of epitaxial layers over the substrate. Referring to the example of FIG. 3, in an embodiment of block 104, an epitaxial stack 212 is formed over the substrate 202. The epitaxial stack 212 includes sacrificial epitaxial layers 214 of a first composition interposed by channel epitaxial layers 216 of a second composition. The first and second composition can be different. In an embodiment, the sacrificial epitaxial layers 214 are formed from SiGe and the channel epitaxial layers 216 are formed from silicon (Si). However, other embodiments are possible including those that provide for a first composition and a second composition having different oxidation rates and/or etch selectivity. In some embodiments, the sacrificial epitaxial layer 214 includes SiGe and the channel epitaxial layer 216 includes silicon (Si). However, other embodiments are possible including those that provide for a first composition and a second composition having different oxidation rates and/or etch selectivity. In some embodiments, the sacrificial epitaxial layer 214 includes SiGe and where the channel epitaxial layer 216 includes Si, the Si oxidation rate of the channel epitaxial layer 216 is less than the SiGe oxidation rate of the sacrificial epitaxial layer 214. It is noted that three (3) layers each of epitaxial layers 214 and 216 are illustrated in FIG. 3, which is for illustrative purposes only and not intended to be limiting beyond what is specifically recited in the claims. In various embodiments, any number of epitaxial layers can be formed in the epitaxial stack 212; the number of layers depending on the desired number of channel regions for the structure 200. In some embodiments, the number of channel epitaxial layers 216 is between 1 and 5, such as 3, 4 or 5.

In some embodiments, the sacrificial epitaxial layer 214 has a thickness ranging from about 4 nm (nanometers) to about 12 nm. The sacrificial epitaxial layers 214 may be substantially uniform in thickness. In some embodiments, the channel epitaxial layer 216 has a thickness ranging from about 3 nm to about 6 nm. In some embodiments, the channel epitaxial layers 216 of the stack are substantially uniform in thickness.

As described in more detail below, the channel epitaxial layer 216 may serve as channel region(s) for a subsequently-formed multi-gate device and its thickness is chosen based on device performance considerations. The sacrificial epitaxial layer 214 may serve to reserve a spacing (or referred to as a gap) between adjacent channel region(s) for a subsequently-formed multi-gate device and its thickness is chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers, such as the channel epitaxial layers 216, include the same material as the substrate 202, such as silicon (Si). In some embodiments, the epitaxially grown layers 214 and 216 include a different material than the substrate 202. As stated above, in at least some examples, the sacrificial epitaxial layer 214 includes an epitaxially grown Si₁₋ₓGeₓ layer (e.g., x is about 25~55%) and the channel epitaxial layer 216 includes an epitaxially grown Si layer. Alternatively, in some embodiments, either of the sacrificial epitaxial layers 214 and channel epitaxial layers 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the sacrificial epitaxial layers 214 and channel epitaxial layers 216 may be chosen based on providing differing oxidation and etch selectivity properties. In various embodiments, the epitaxial layers 214 and 216 are substantially dopant-free (i.e., having an extrinsic dopant concentration from about 0 cm⁻³ to about 1×10¹⁷ cm⁻³), where for example, no intentional doping is performed during the epitaxial growth process.

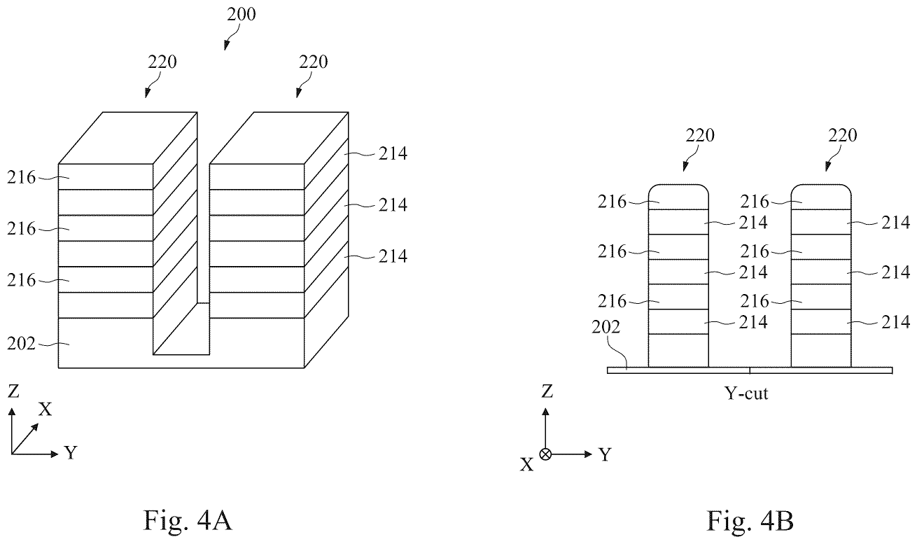

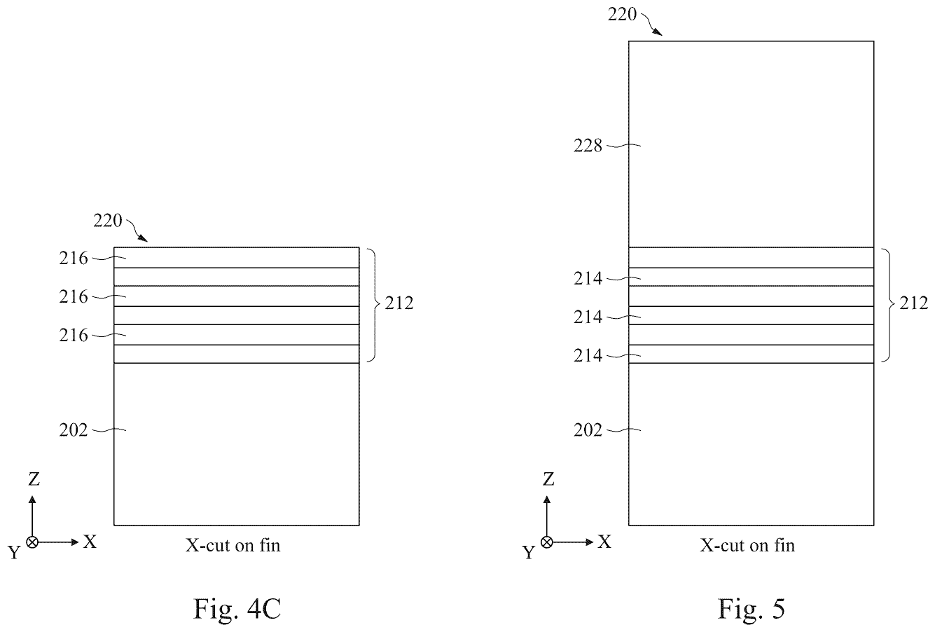

At block 106, the example method 100 includes patterning the epitaxial stack to form semiconductor fins (also referred to as fins). Referring to the example of FIGS. 4A, 4B, and 4C, in an embodiment of block 106, a plurality of fins 220 extending from the substrate 202 are formed. In various embodiments, each of the fins 220 includes an upper portion of the interleaved epitaxial layers 214 and 216 and a bottom portion protruding from the substrate 202.

The fins 220 may be fabricated using suitable processes including photolithography and etch processes. The photolithography process may include forming a photoresist layer over the substrate 202 (e.g., over the epitaxial stack 212), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate 202, and epitaxial stack 212 formed thereupon, while an etch process forms trenches in unprotected regions through masking layer(s) such as hard mask, thereby leaving the plurality of extending fins. The trenches may be etched using a dry etch (e.g., reactive ion etching), a wet etch, and/or other suitable processes. The trenches may be filled with dielectric material forming, for example, shallow trench isolation features interposing the fins.

At block 108, the example method 100 includes forming one or more sacrificial layers/features over the substrate. Referring to the example of FIG. 5, in an embodiment of block 108, a sacrificial gate dielectric layer (not shown) is blanket deposited over a stop layer 222, which is formed over the fin 220, which is formed over the substrate 202. A sacrificial gate electrode layer 228 is then blanket deposited on the sacrificial gate dielectric layer and over the substrate 202. The sacrificial gate electrode layer 228 includes silicon such as polycrystalline silicon or amorphous silicon. The thickness of the sacrificial gate dielectric layer is in a range from about 1 nm to about 5 nm in some embodiments. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer 228 may be deposited using CVD, including LPCVD and PECVD, PVD, ALD, or other suitable processes.

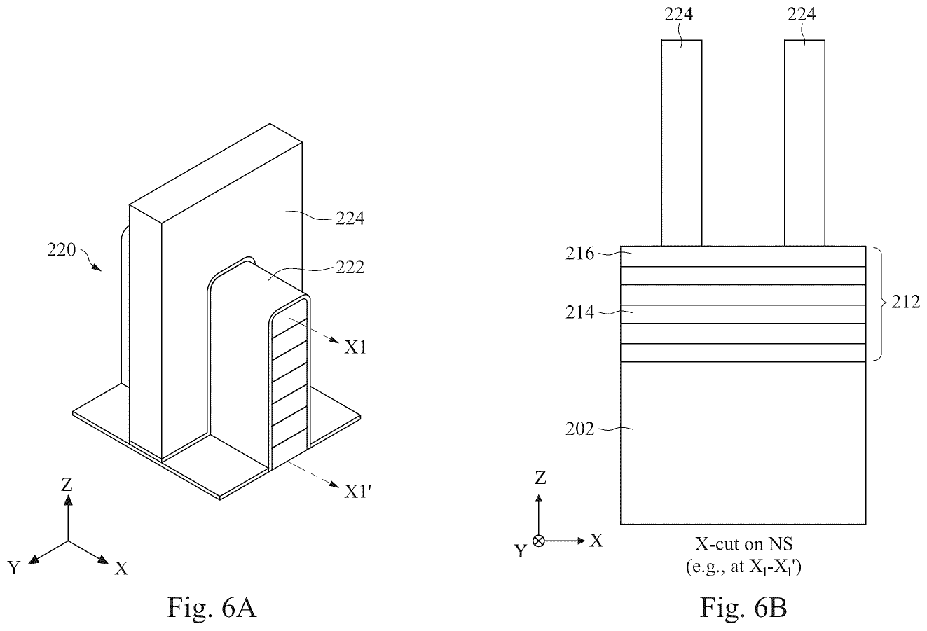

At block 110, the example method 100 includes patterning the one or more sacrificial layers/features to form a dummy gate structure on channel regions of the fins. Referring to the example of FIGS. 6A and 6B, in an embodiment of block 110, a sacrificial gate structure 224 is formed over portions of the fins 220 which are to be channel regions. The sacrificial gate structure 224 defines the channel regions of a GAA device. The sacrificial gate structure 224 includes a sacrificial gate dielectric layer and a sacrificial gate electrode layer 228. The sacrificial gate structure 224 is formed by forming a mask layer over the sacrificial gate electrode layer. The mask layer may include a pad silicon oxide layer and a silicon nitride mask layer. Subsequently, a patterning operation is performed on the mask layer and sacrificial gate dielectric and electrode layers are patterned into the sacrificial gate structure 224. By patterning the sacrificial gate structure 224, the fins 220 are partially exposed on opposite sides of the sacrificial gate structure 224, thereby defining source/drain (S/D) regions. In this disclosure, a source and a drain are interchangeably used, and the structures thereof are substantially the same.

The sacrificial gate structure 224 is subsequently removed as discussed with reference to block 130 of the method 100 and will be replaced by a final gate stack at a subsequent processing stage of the structure 200. In particular, the sacrificial gate structure 224 is replaced at a later processing stage by a high-K dielectric layer (HK) and metal gate electrode (MG) as discussed below.

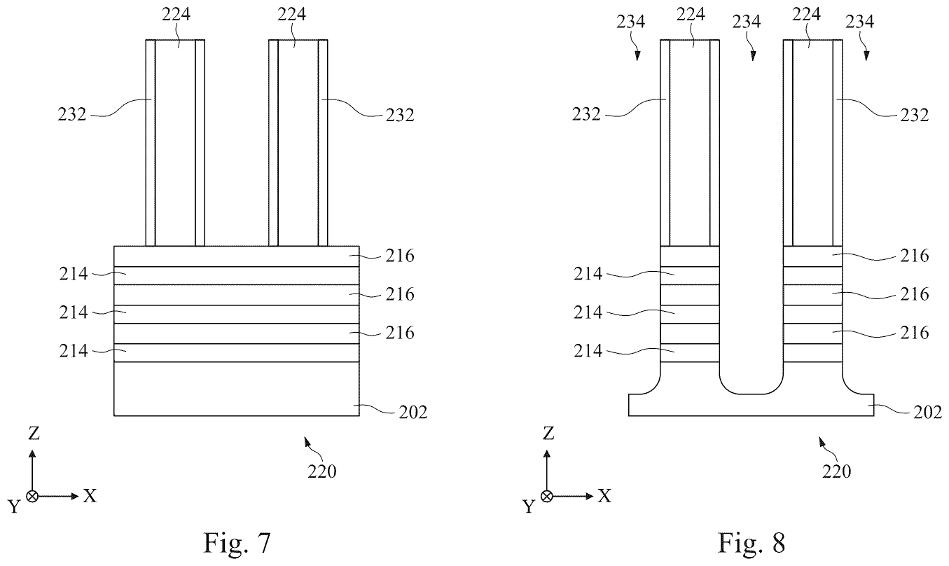

At block 112, the example method 100 includes forming gate sidewall spacers on sidewalls of the sacrificial gate structure. Referring to the example of FIG. 7, in an embodiment of block 112, gate sidewall spacers 232 are formed on sidewalls of the sacrificial gate structure 224. In various embodiments, the gate sidewall spacers 232 may include a dielectric material such as silicon oxide (SiOₓ), silicon nitride (SiN), silicon carbide (SiC), silicon oxynitride (SiON), SiCN films, silicon oxycarbide (SiOC), Silicon oxycarbonitride (SiOCN) films, and/or combinations thereof. In some embodiments, the gate sidewall spacers 232 include multiple layers, such as main spacer walls, liner layers, and the like. By way of example, the gate sidewall spacers 232 may be formed by depositing a dielectric material layer over the sacrificial gate structure 224 using processes such as, a CVD process, a sub atmospheric CVD (SACVD) process, a flowable CVD process, an ALD process, a PVD process, or other suitable process. In some embodiments, the deposition of the dielectric material layer is followed by an etching-back (e.g., anisotropically) process to expose portions of the fin 220 adjacent to and not covered by the sacrificial gate structure 224 (e.g., S/D regions). The dielectric material layer may remain on the sidewalls of the sacrificial gate structure 224 as gate sidewall spacers 232. In some embodiments, the etching-back process may include a wet etch process, a dry etch process, a multiple-step etch process, and/or a combination thereof. The gate sidewall spacers 232 may have a thickness ranging from about 5 nm to about 20 nm.

At block 114, the example method includes recessing the fins in the source drain/regions. Referring to the example of FIG. 8, in an embodiment of block 114, the fin 220 is recessed in the source drain/regions. The stacked epitaxial layers 214 and 216 are etched down at the S/D regions to form a recess 234. In various embodiments, the recessing is performed by a suitable etching process, such as a dry etching process, a wet etching process, or an RIE process. Dry etching may be implemented using an etchant including a bromine-containing gas (e.g., HBr and/or CHBR3), a fluorine-containing gas (e.g., CF₄, SF₆, CH₂F₂, CHF₃, and/or C₂F₆), other suitable gases, or combinations thereof.

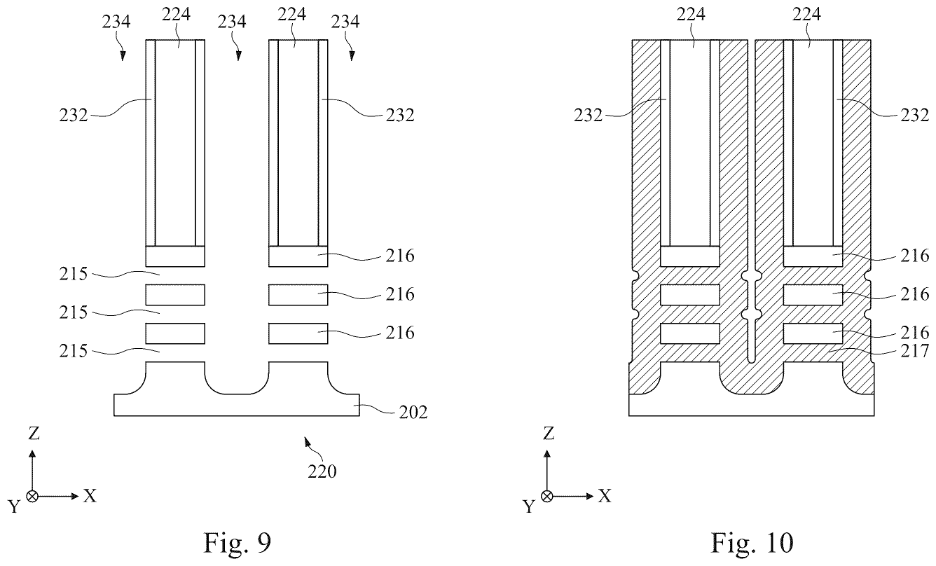

At block 116, the example method 100 includes removing the sacrificial epitaxial layers forming spaces between the channel epitaxial layers. Referring to the example of FIG. 9, in an embodiment of block 116, sacrificial epitaxial layers 214 have been removed and spaces 215 have been formed. The sacrificial epitaxial layers 214 can be removed or etched using an etchant that can selectively etch the sacrificial epitaxial layers 214 against the channel epitaxial layers 216.

When the sacrificial epitaxial layers 214 comprise Ge or SiGe and the channel epitaxial layers 216 comprise Si, the sacrificial epitaxial layers 214 can be selectively removed using a wet etchant such as, but not limited to, ammonium hydroxide (NH₄OH), tetramethylammonium hydroxide (TMAH), ethylenediamine pyrocatechol (EDP), or potassium hydroxide (KOH) solutions. In various embodiments, the plurality of sacrificial epitaxial layers 214 were selectively removed via a selective removal process that included oxidizing the plurality of sacrificial epitaxial layers 214 using a suitable oxidizer, such as ozone. Thereafter, the oxidized sacrificial epitaxial layers 214 were selectively removed via a dry etching process, for example, by applying an HCl gas at a temperature of about 500 degrees Celsius to about 700 degrees Celsius, or applying a gas mixture of CF₄, SF₆, and CHF₃.

At block 118, the example method 100 includes depositing a sacrificial refill layer (e.g., depositing a refill layer using well known deposition techniques, such as chemical vapor deposition (CVD), or possibly thermally grown, or using some other conventional technique) in area vacated by the removed sacrificial epitaxial layers. In various embodiments, the refill layer may include an oxide layer such as a silicon oxide compound. In various embodiments, the silicon oxide compound may include SiO₂, SiOH, SiOC, SiOCH, or others. Referring to the example of FIG. 10, in an embodiment of block 118 a sacrificial refill layer 217, such as silicon oxide or the like, is formed in the area vacated by the removed sacrificial epitaxial layers 214. In various embodiments forming an oxide layer includes depositing the sacrificial refill layer over the semiconductor structure 200.

At block 120, the example method 100 includes selectively removing portions of the sacrificial refill layer between adjacent fins. The selectively removing portions of the sacrificial refill layer between adjacent fins includes using a plurality of selective sacrificial refill layer removal sequences to selectively remove portions of the sacrificial refill layer between the adjacent fins. The plurality of selective sacrificial refill layer removal sequences include at least a first selective sacrificial refill layer removal sequence followed by a second selective sacrificial refill layer removal sequence. Each selective sacrificial refill layer removal sequence includes a treatment phase and a breakthrough removal phase. The treatment phase softens an outer layer of the sacrificial refill layer, and the breakthrough removal phase removes the softened outer layer of the sacrificial refill layer. The sequence of the treatment phase and the breakthrough removal phase is repeated for a plurality of cycles, such as, 2 or 3 cycles or more, until a desired level of selective sacrificial refill layer has been removed. Referring to the example of FIG. 11, in an embodiment of block 120, portions of the sacrificial refill layer 217 have been removed between adjacent fins 220.

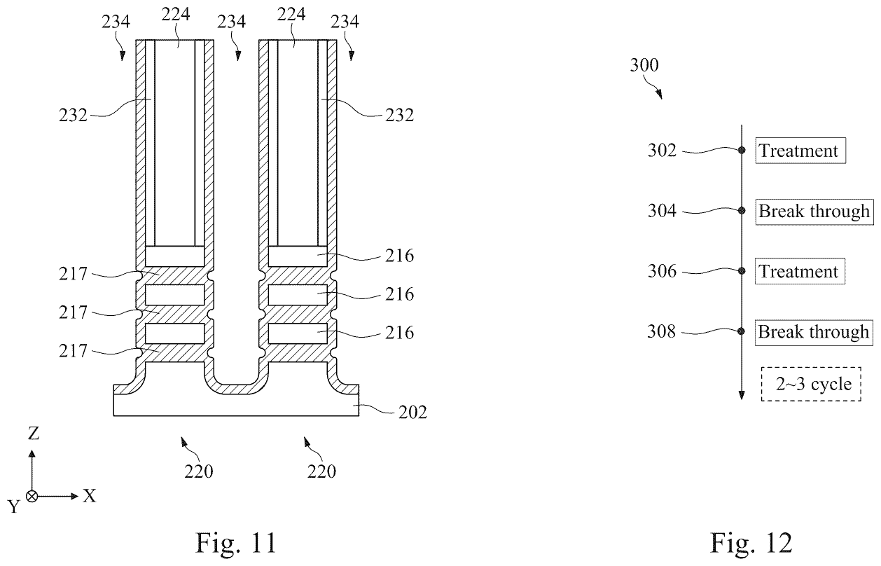

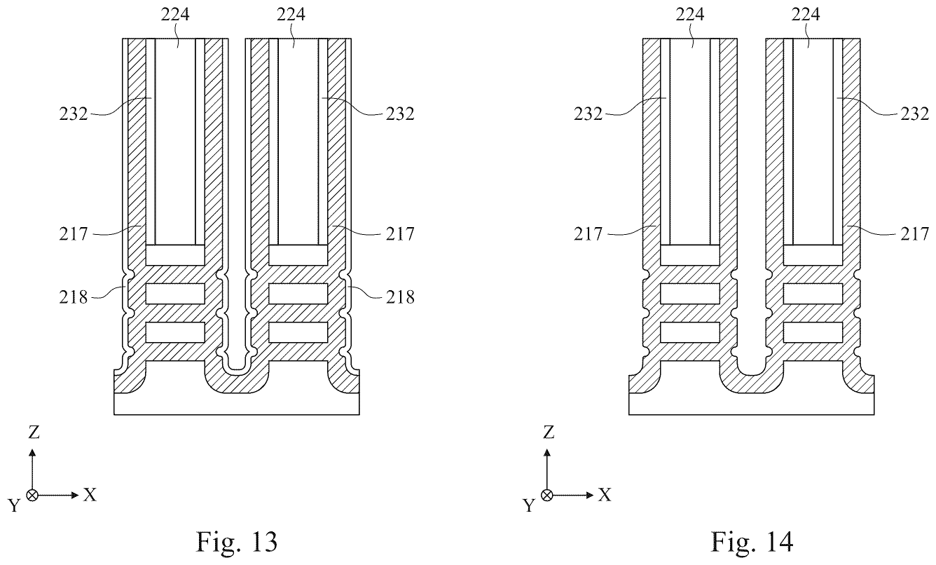

FIG. 12 is a flow chart depicting an example method 300 for selectively removing portions of the sacrificial refill layer between adjacent fins. FIG. 12 is described in conjunction with FIGS. 13-16, which illustrate the semiconductor structure 200 at various stages of fabrication in accordance with some embodiments. In this example, the example method 300 includes a first selective sacrificial refill layer removal sequence comprising a first treatment phase 302 and a first breakthrough phase 304 followed by a second selective sacrificial refill layer removal sequence comprising a second treatment phase 306 and a second breakthrough phase 308. The treatment phases soften an outer layer of the sacrificial refill layer, and the breakthrough removal phases remove the softened outer layer of the sacrificial refill layer. The selective sacrificial refill layer removal sequence may be repeated for additional cycles.

Referring to the example of FIG. 13, in an embodiment of the first treatment phase 302, an outer portion of the sacrificial refill layer 217 has been treated. In various embodiments, the treatment includes a H₂ treatment wherein an outer layer of the sacrificial refill layers 217 is bombarded with H₂. In various embodiments, the H₂ treatment creates a softened region 218 of the sacrificial refill layers 217. In various embodiments, the H₂ treatment creates the softened region 218 with a depth of approximately 1 nanometer (nm) to approximately 1.5 nm. In various embodiments, the H₂ treatment operations include bombarding the surface of the sacrificial refill layers 217 with H₂ for approximately 2-3 seconds, using: a dilute gas comprising one or more of He, Ar, N₂, or others; at a power between approximately 10 W to approximately 4000 W; at a pressure of approximately 1 mT to approximately 100 mT; and a gas flow of approximately 20 sccm (standard cubic centimeter per minute) to approximately 3000 sccm.

Referring to the example of FIG. 14, in an embodiment of the first breakthrough removal phase 304, the softened region 218 of the sacrificial refill layer has been removed. In various embodiments, the breakthrough removal operations include etching the softened region 218 from the surface of the sacrificial refill layers 217 using: an etch gas, such as CHF₃, CF₄, CH₂F₂, NF₃, or others; a dilute gas comprising one or more of He, Ar, N₂, or others; at a power between approximately 10 W to approximately 4000 W; at a pressure of approximately 1 mT to approximately 800 mT; and a gas flow of approximately 20 sccm to approximately 3000 sccm.

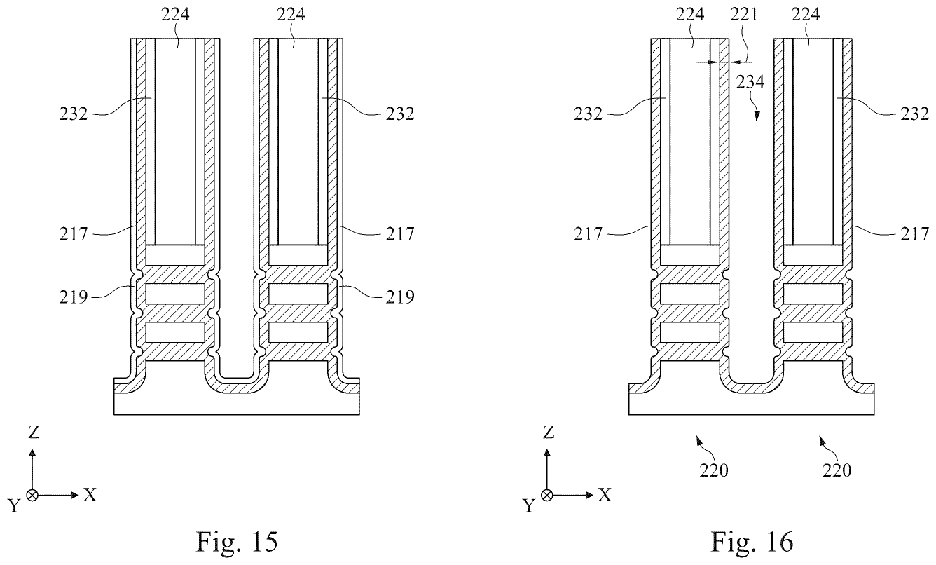

Referring to the example of FIG. 15, in an embodiment of the second treatment phase 306, an outer portion of the sacrificial refill layer 217 has been treated. In various embodiments, the treatment includes a H₂ treatment wherein an outer layer of the sacrificial refill layers 217 is bombarded with H₂. In various embodiments, the H₂ treatment creates a softened region 219 of the sacrificial refill layers 217. In various embodiments, the H₂ treatment creates the softened region 219 with a depth of approximately 1 nanometer (nm) to approximately 1.5 nm. In various embodiments, the H₂ treatment operations include bombarding the surface of the sacrificial refill layers 217 with H₂ for approximately 2-3 seconds using: a dilute gas comprising one or more of He, Ar, N₂, or others; at a power between approximately 10 W to approximately 4000 W; at a pressure of approximately 1 mT to approximately 100 mT; and a gas flow of approximately 20 sccm (standard cubic centimeter per minute) to approximately 3000 sccm.

Referring to the example of FIG. 16, in an embodiment of the second breakthrough removal phase 308, the softened region 219 of the sacrificial refill layer has been removed. In various embodiments, the breakthrough removal operations include etching the softened region 219 from the surface of the sacrificial refill layers 217 using: an etch gas, such as CHF₃, CF₄, CH₂F₂, NF₃, or others; a dilute gas comprising one or more of He, Ar, N₂, or others; at a power between approximately 10 W to approximately 4000 W; at a pressure of approximately 1 mT to approximately 800 mT; and a gas flow of approximately 20 sccm (standard cubic centimeter per minute) to approximately 3000 sccm. In this example, the sacrificial refill layers 217 have a final depth 221 of approximately 2 nm to approximately 3 nm.

Excessive accumulation of the sacrificial refill layer (e.g., silicon oxide) on the bottom of the recess 234 can lead to a metal gate to metal gate short between metal gates of adjacent fins 220 during subsequent metal gate replacement operations. By continuously cycling through the selective sacrificial refill layer removal sequences until a desired final depth 221 of sacrificial refill layers 217 is achieved, excessive accumulation of the sacrificial refill layer (e.g., silicon oxide) on the bottom of the recess 234 between adjacent fins 220 can be prevented.

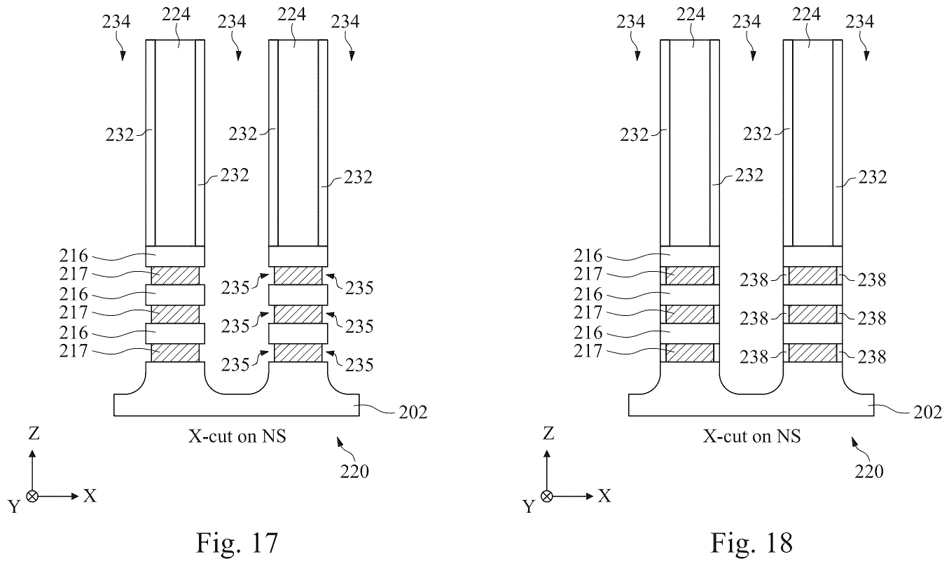

Referring again to FIG. 1, at block 122, the example method 100 includes forming a recess in the sacrificial refill layers. Referring to the example of FIG. 17, in an embodiment of block 122, the sacrificial refill layers 217 have been etched back forming sacrificial refill layer recesses 235 bounded on the top and bottom by channel epitaxial layers 216 and laterally by the recessed sacrificial refill layers 217. The sacrificial refill layers 217 can be selectively etched by using an etchant including HF, NH₃, or a combination thereof.

At block 124, the example method 100 Includes forming an inner spacer layer in the sacrificial refill layer recesses. Forming the inner spacer layer may include depositing inner spacer material in the sacrificial refill layer recesses, and trimming the inner spacer layers (e.g., via etching operations). Referring to the example of FIG. 18, in an embodiment of block 124, inner spacer layers 238 are formed in the sacrificial refill layer recesses 235. The inner spacer layers 238 may be formed from silicon oxides, silicon nitrides, silicon carbides, silicon carbide nitride, silicon oxide carbide, silicon carbide oxynitride, and/or other suitable dielectric materials. In some embodiments, the inner spacer layer 238 is deposited as a conformal layer. The inner spacer layers 238 can be formed by ALD or any other suitable method. In various embodiments, the inner spacer layers 238 are formed from the same material as the gate sidewall spacers 232. In various embodiments, the gate sidewall spacers 232 and the inner spacer layers 238 are formed from SiOCN.

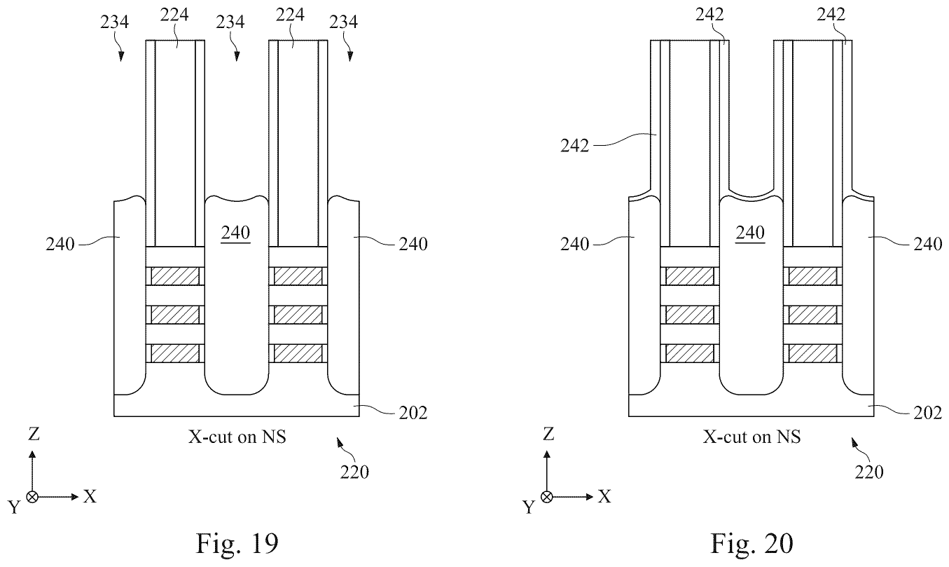

At block 126, the example method 100 Includes forming source/drain (S/D) features. Forming the S/D features may involve depositing pure silicon in the recess 234 in the source drain/regions. Referring to the example of FIG. 19, in an embodiment of block 126, epitaxial S/D features 240 are formed in recess 234. In some embodiments, the epitaxial S/D features 240 include silicon for NFETs and SiGe for PFETs. In some embodiments, the epitaxial S/D features 240 are formed by an epitaxial growth method using CVD, ALD, or molecular beam epitaxy (MBE). The epitaxial S/D features 240 are formed in contact with the channel epitaxial layers 216 and separated from the sacrificial refill layers 217 by the inner spacer layers 238.

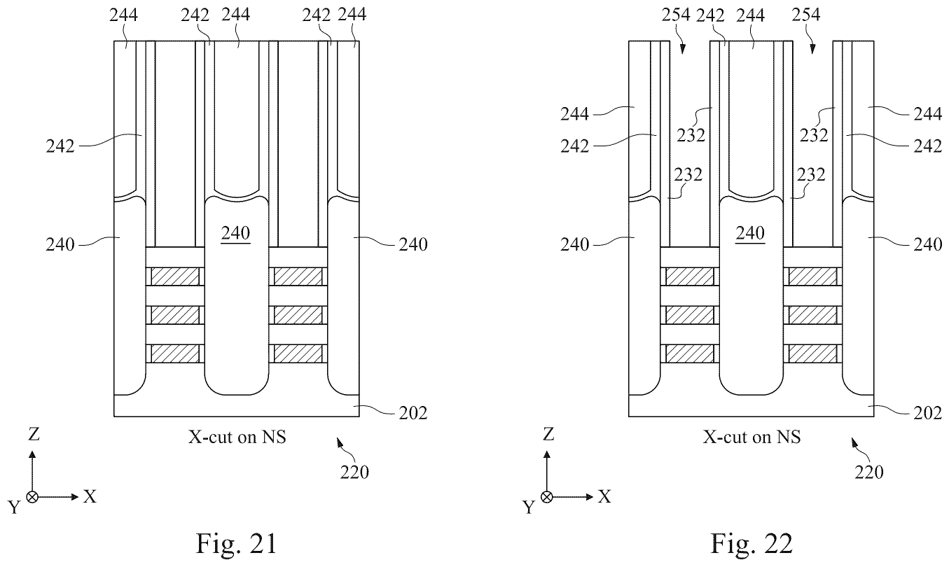

At block 128, the example method 100 includes forming a CESL layer. Referring to the example of FIG. 20, in an embodiment of block 128, a CESL layer 242 is formed over the S/D features 240. The CESL layer 242 may comprise silicon nitride, silicon oxynitride, silicon nitride with oxygen (O) or carbon (C) elements, and/or other materials; and may be formed by CVD, PVD (physical vapor deposition), ALD, or other suitable methods. In various embodiments, the CESL layer 242 is formed from SiN.

At block 130, the example method 100 includes forming an ILD layer. Referring to the example of FIG. 21, in an embodiment of block 130, an interlayer dielectric layer (ILD layer 244) is formed over the CESL layer 242. The ILD layer 244 may comprise tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 244 may be formed by PECVD, flowable CVD (FCVD), or other suitable methods. In some embodiments, forming the ILD layer 244 further includes performing a CMP process to planarize a top surface of the structure 200, such that the top surfaces of the sacrificial gate structure 224 are exposed.

At block 132, the example method 100 includes removing the dummy gate stack to form a gate trench. Referring to the example of FIG. 22, in an embodiment of block 132, the sacrificial gate structure 224 has been removed to form a gate trench 254. The gate trench 254 exposes the fin 220 in the channel region(s). The ILD0 layer 244 and the CESL layer 242 protects the epitaxial S/D features 240 during the removal of the sacrificial gate structure 224. The sacrificial gate structure 224 can be removed using plasma dry etching and/or wet etching. When the sacrificial gate electrode layer is polysilicon and the ILD0 layer 244 is an oxide, a wet etchant such as a TMAH solution can be used to selectively remove the sacrificial gate electrode layer. The sacrificial gate dielectric layer is thereafter removed using plasma dry etching and/or wet etching.

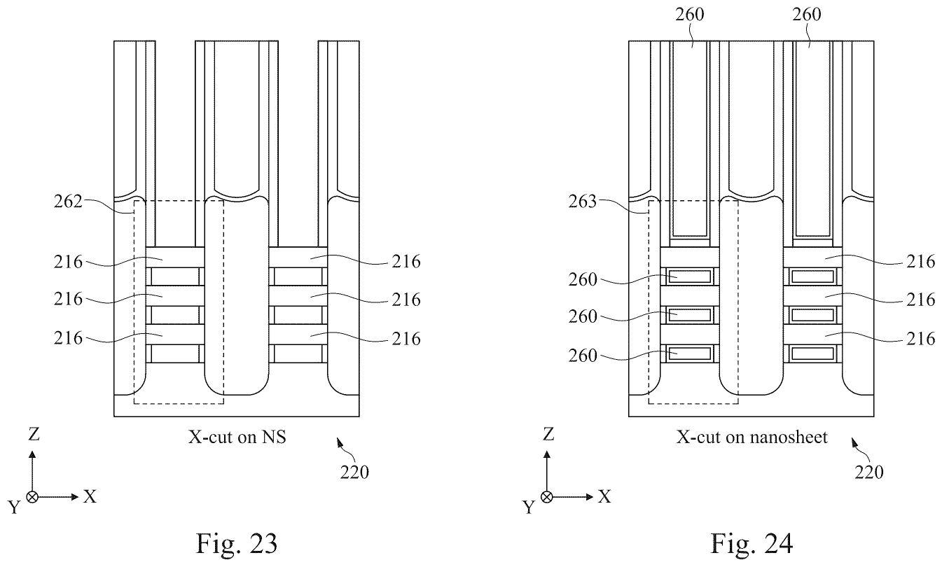

At block 134, the example method 100 includes removing the sacrificial refill layers and releasing the nanosheets. Referring to the example of FIG. 23, in an embodiment of block 134, sacrificial refill layers 217 have been removed thereby releasing channel members from the channel region of the GAA device. In the illustrated embodiment, channel members are channel epitaxial layers 216 in the form of nanosheets. In various embodiments, the channel epitaxial layers 216 include silicon. In various embodiments, the plurality of sacrificial refill layers 217 were selectively removed via a selective removal process that included using an etchant including HF, NH3, or a combination thereof.

At block 136, the example method 100 includes forming metal gate structures. Referring to the example of FIG. 24, in an embodiment of block 136, a gate structure 260 is formed. In various embodiments, the gate structure 260 is the gate of a multi-gate transistor. In various embodiments, the gate structure 260 is a high-K metal gate stack, however other compositions are possible. In various embodiments the high-K metal gate stack includes a gate dielectric layer that includes an interfacial layer and a high-k dielectric layer. The high-k dielectric layer wraps each of the nanosheets 216, and the interfacial layer is interposed between the high-k dielectric layer and the nanosheets 216. The interfacial layer may include a dielectric material such as silicon oxide (SiO₂) or silicon oxynitride (SiON), and may be formed by chemical oxidation, thermal oxidation, atomic layer deposition (ALD), CVD, and/or other suitable methods. The high-k dielectric layer may include hafnium oxide (HfO₂), hafnium silicon oxide (HfSiO), hafnium silicon oxynitride (HfSiON), hafnium tantalum oxide (HMO), hafnium titanium oxide (HfTiO), hafnium zirconium oxide (HfZrO), other suitable high-k dielectric materials, and/or combinations thereof. The high-k material may further be selected from metal oxides, metal nitrides, metal silicates, transition metal-oxides, transition metal-nitrides, transition metal-silicates, oxynitrides of metals, metal aluminates, zirconium silicate, zirconium aluminate, silicon oxide, silicon nitride, silicon oxynitride, zirconium oxide, titanium oxide, aluminum oxide, hafnium dioxide-alumina (HfO₂—Al₂O₃) alloy, other suitable materials, and/or combinations thereof. The high-k dielectric layer may be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof. In one embodiment, the gate dielectric layer is formed using a highly conformal deposition process such as ALD in order to ensure the formation of a gate dielectric layer having a uniform thickness around each channel layer. The high-K metal gate structures may include additional material layers.

At block 138, the example method 100 includes performing further fabrication. A semiconductor device may undergo further processing to form various features and regions known in the art. For example, subsequent processing may include filling the opening over the source/drain regions with ILD1 material to fill in the ILD1 layer and forming one or more intermetal dielectric (IMD) layers over the ILD1 layer. Each IMD layer may include an etch stop layer (ESL) above the underlying layer and an ILD layer above the ESL. The ESL may be deposited using one or more low temperature deposition processes such as chemical vapor deposition, physical vapor deposition, or atomic layer deposition. Subsequent processing may also include forming contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 100, and some process steps described above may be replaced or eliminated in accordance with various embodiments of the method 100.

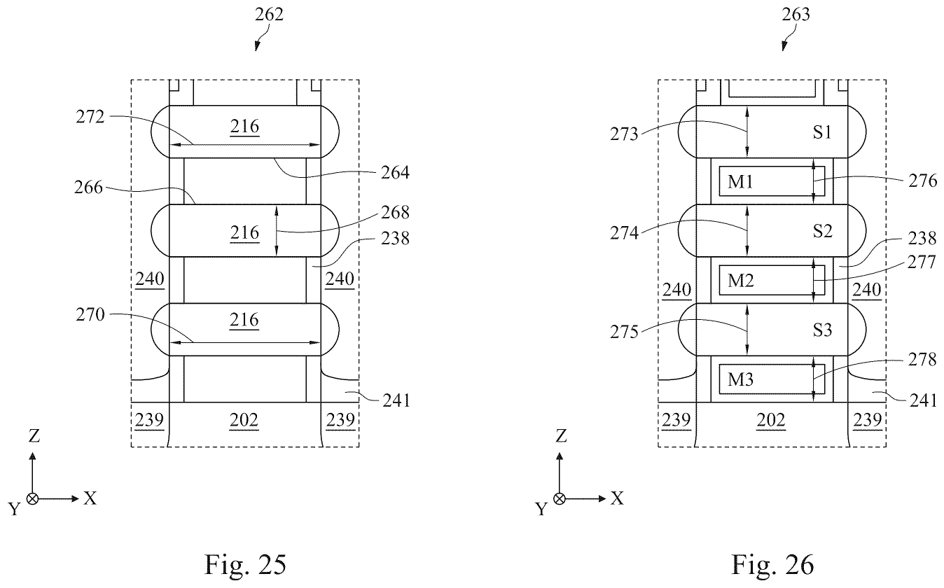

Without replacement of sacrificial SiGe layer with sacrificial refill layer, nanosheets may become narrower in height in middle sections leading to lower resistance nanosheets during metal gate replacement operations. Use of sacrificial refill layer can solve the issue with nanosheets getting narrower in height in middle sections. However, other phenomena such as width of bottom sacrificial layer being wider than width of top sacrificial layer may occur leading to width at bottom of gate being wider than width at upper gate section. Also bottom of gate can potentially short to bottom of adjacent gate due to incomplete oxide removal between adjacent fins during oxide recess operations during formation of inner spacers and spacer material being formed between gates on adjacent fins. Use of both the sacrificial refill layer and the use of the plurality of selective sacrificial refill layer removal sequences comprising a treatment phase and a breakthrough phase can prevent both phenomenon. FIGS. 25-27 illustrate how the use of both the sacrificial refill layer and the use of the plurality of selective sacrificial refill layer removal sequences comprising a treatment phase and a breakthrough phase can prevent both phenomenon.

FIG. 25 is a cross-sectional schematic diagram illustrating region 262 (FIG. 23) after removing the sacrificial refill layers and releasing the nanosheets (e.g., block 134 of method 100). Illustrated are the channel region of the substrate 202, released nanosheets 216, inner spacer layers 238, source/drain features 240, STI features 239, and dielectric material 241 (e.g., Si-based SiO, SiN, SiCn, SiON, SiOCN). The released nanosheets 216 have a rectangular-like shape.

If the sacrificial epitaxial layers 214 had not been replaced with the sacrificial refill layers 217 before inner spacer layer formation, removing the sacrificial epitaxial layers 214 and releasing the nanosheets 216 may result in the loss of Si in the nanosheets 216 at the top edge 264 of the nanosheets 216 and/or bottom edge 266 of the nanosheets 216, leaving the top edge 264 and/or the bottom edge 266 with curved edges that curve inwardly into the nanosheets 216. This loss of Si could result in the nanosheets 216 having a concave-like shape, higher channel resistance and lower DC transistor performance. The loss of Si could result in the height 268 of nanosheets 216 being between approximately 1.5 nm to approximately 2.5 nm narrower in middle regions of the nanosheets 216 than in outer regions of the nanosheets 216 without the use of the sacrificial refill layers 217. On the other hand, the use of the sacrificial refill layers 217 could reduce the loss of Si in the nanosheets 216 during nanosheets 216 releasing operations and lead to the height 268 in middle regions of the nanosheets 216 being less than 1 nm shorter than the height in outer regions of the nanosheets 216.

The use of the sacrificial refill layers 217, however, could result in the bottom nanosheet 216 having a width 270 that is wider than a width 272 of the top nanosheet. In some embodiments, the width 270 may be approximately 4 nm to approximately 5 nm wider than the width 272. The lengthened width 270 of the bottom nanosheet could result in gate-to-gate shorting between nanosheets in adjacent fins. By using a plurality of selective sacrificial refill layer removal sequences comprising a treatment phase and a breakthrough phase, the difference in width between width 270 and width 272 may be reduced to less than 1 nm (e.g., width 270>width 272, and width 270−width 272<1 nm). Also, the likelihood of gate-to-gate shorting between nanosheets in adjacent fins can be substantially eliminated.

FIG. 26 is a cross-sectional schematic diagram illustrating region 263 (FIG. 24) after metal gate replacement operations (e.g., block 136 of method 100). Illustrated are the channel region of the substrate 202, released nanosheets (with top nanosheet S1, middle nanosheet S2, and bottom nanosheet S3), inner spacer layers 238, source/drain features 240, STI features 239, dielectric material 241 (e.g., Si-based SiO, SiN, SiCn, SiON, SiOCN), and replacement metal gate structure (with top gate section M1, middle gate section M2, and bottom gate section M3). The top nanosheet S1, middle nanosheet S2, and bottom nanosheet S3 have a rectangular-like shape, and gate section M1, gate section M2, and gate section M3 have a rectangular-like shape.

The top nanosheet S1 has a thickness 273, the middle nanosheet S2 has a thickness 274, and the bottom nanosheet S3 has a thickness 275, wherein thickness 273 is approximately equal to thickness 274 and thickness 274 is approximately equal to thickness 275. In various embodiments, thickness 273, thickness 274, and thickness 275 are approximately equal to 9 nm to approximately 10 nm.

The top gate section M1 has a thickness 276, the middle gate section M2 has a thickness 277, and the bottom gate section M3 has a thickness 278, wherein thickness 276 is approximately equal to thickness 277 and thickness 277 is approximately equal to thickness 278. In various embodiments, thickness 276, thickness 277, and thickness 278 are approximately equal to 7 nm to approximately 8 nm.

Without the use of the sacrificial refill layers 217, the thickness 273 may be approximately equal to 6.5 nm to approximately 7.5 nm and the thickness 274 and the thickness 275 may be approximately equal to 4 nm to approximately 6 nm. Also, without the use of the sacrificial refill layers 217, the thickness 276, the thickness 277, and the thickness 278 may be approximately equal to 8.7 nm to approximately 10.7 nm.

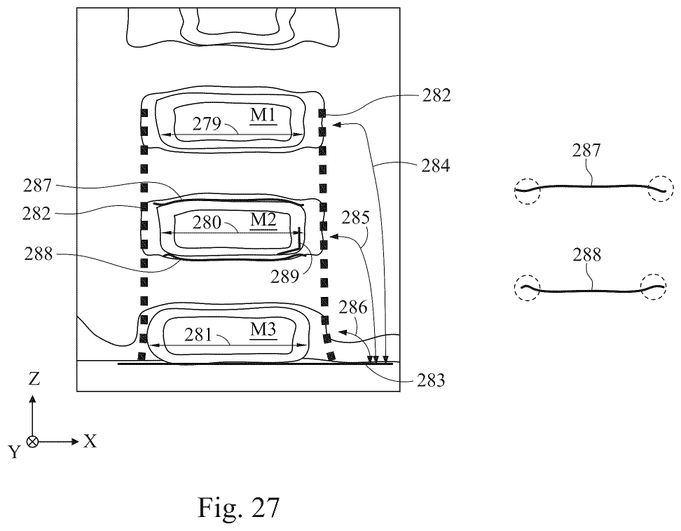

FIG. 27 is a cross-sectional diagram illustrating an example region 263 (FIG. 24) after metal gate replacement operations (e.g., block 136 of method 100). In this example, the top gate section M1 has a width 279, the middle gate section M2 has a width 280, and the bottom gate section M3 has a width 281, wherein width 279 is approximately equal to width 280 and width 280 is approximately equal to width 281. In various embodiments, width 279, width 280, and width 281 differ by less than 1 nm. In various embodiments, width 281 minus width 280 is between 0 to approximately 1 nm. In various embodiments, width 280 minus width 279 is between 0 to approximately 0.5 nm. In various embodiments, the ratio of width 279 (W1) to width 280 (W2) is approximately 0.95 to approximately 0.97 (W1/W2=~0.95~−0.97). In various embodiments, the ratio of width 279 (W1) to width 281 (W3) is approximately 0.93 to approximately 0.94 (W1/W3=~0.93~−0.94). In various embodiments, the ratio of width 280 (W2) to width 281 (W3) is approximately 0.95 to approximately 0.97 (W2/W3=~0.95~−0.97). In various embodiments, the ratio of the upper width (e.g., W1) to the lower width (e.g., W3) is approximately 0.93 to approximately 0.97 (W(upper)/W(lower)=~0.93~−0.97). With the use of the sacrificial refill layers 217, the likelihood of gate-to-gate shorting between gates in adjacent fins can be substantially eliminated.

Without the use of the sacrificial refill layers 217, width 281 may be greater than width 279 by approximately 4 nm to approximately 5 nm, width 281 minus width 280 may between approximately 2.5 to approximately 3 nm, and width 280 minus width 279 may be between approximately 1.5 nm to approximately 2 nm.

In this example, a tangent line 282 is defined along the outer sidewall edge of gate spacers for the top gate section M1, the middle gate section M2, and the bottom gate section M3. A first angle 284 is defined between a horizontal line 283 under bottom gate section M3 and the tangent line 282 at the top gate section M1, a second angle 285 is defined between the horizontal line 283 under bottom gate section M3 and the tangent line 282 at the middle gate section M2, and a third angle 286 is defined between the horizontal line 283 under bottom gate section M3 and the tangent line 282 at the bottom gate section M3.

In various embodiments, the first angle 284 has a magnitude between approximately 90° to approximately 91°; the second angle 285 has a magnitude between approximately 92° to approximately 93°; and the third angle 286 has a magnitude between approximately 94° to approximately 98°. Without the use of the sacrificial refill layers 217 and without the use of the plurality of selective sacrificial refill layer removal sequences comprising a treatment phase and a breakthrough phase, the first angle 284 may have a magnitude between approximately 93° to approximately 94°; the second angle 285 may have a magnitude between approximately 95° to approximately 97°; and the third angle 286 has a magnitude between approximately 105° to approximately 115°.

In this example, the metal gate structures have a top edge 287 that is relatively straight and a bottom edge 288 that is relatively straight. In this example a gate angle 289 is defined between the bottom edge 288 and a sidewall edge of the gate structure. In various embodiments the gate angle 289 is between approximately 100.3° and approximately 100.9°. Without the use of the sacrificial refill layers 217, the gate angle 289 may be between approximately 155° and approximately 159° due to the curvature of the gate structure.

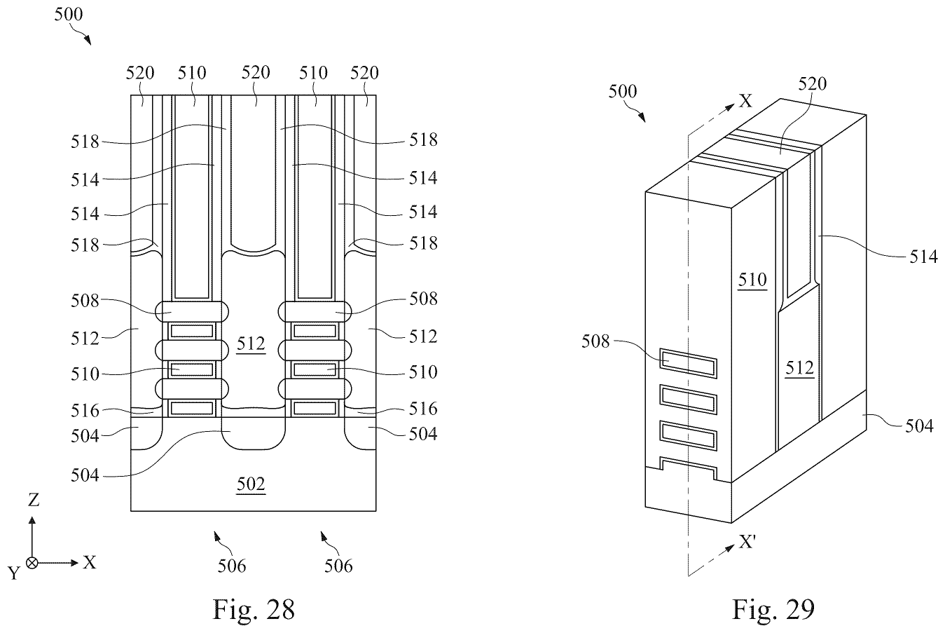

FIGS. 28-29 illustrate an example semiconductor structure 500 (e.g., semiconductor structure 200) after subsequent metal gate fabrication operations. FIG. 28 provides a cross-sectional schematic view along the X-X′ cutline, and FIG. 29 provides a three dimensional schematic view. The example semiconductor structure 500 includes a substrate 502, STI features 504 disposed on the substrate 502 and separating a plurality of fin structures 506, channel nanosheets 508, high-K (HK) metal gate structures 510 (with HK dielectric, such as: HfO, TaN, and Metal, such as: W, Cu, Co) surrounding the channel nanosheets 508, source drain regions 512, gate sidewall spacers 514 (e.g.: SiCN, SiOCN, SiON, SiN), inner spacer layers 516 (e.g.: SiCN, SiOCN, SiON, SiN), CESL 518, and ILD layers 520.

In some aspects, the techniques described herein relate to a method, including: providing a semiconductor structure including a plurality of vertically spaced channel structures and a plurality of vertically spaced sacrificial epitaxial layers positioned between the plurality of vertically spaced channel structures, a sacrificial gate structure formed over the semiconductor structure, and gate sidewall spacers formed on sidewalls of the sacrificial gate structure; recessing the semiconductor structure in source and drain regions; removing the vertically spaced sacrificial epitaxial layers from between the plurality of vertically spaced channel structures; depositing sacrificial refill layer material over and around the semiconductor structure; selectively etching the sacrificial refill layer material using a selective removal sequence until a desired level of the sacrificial refill layer material has been removed, wherein the selective removal sequence includes a treatment phase and a removal phase, wherein the treatment phase includes softening an outer portion of the sacrificial refill layer material and the removal phase includes removing the softened outer portion of the sacrificial refill layer material; forming an inner spacer layer at sidewalls of the sacrificial refill layer material; forming source/drain features; and replacing the sacrificial gate structure and the sacrificial refill layer material with a metal gate structure.

In some aspects, the techniques described herein relate to a method, wherein the sacrificial refill layer material includes a silicon oxide compound.

In some aspects, the techniques described herein relate to a method, wherein the sacrificial refill layer material includes SiO₂, SiOH, SiOC, or SiOCH.

In some aspects, the techniques described herein relate to a method, wherein softening the outer portion of the sacrificial refill layer material includes bombarding the outer portion with a gas.

In some aspects, the techniques described herein relate to a method, wherein softening the outer portion of the sacrificial refill layer material includes bombarding the outer portion with a H₂.

In some aspects, the techniques described herein relate to a method, wherein softening the outer portion of the sacrificial refill layer material includes creating a softened region with a depth of approximately 1 nanometer (nm) to approximately 1.5 nm.

In some aspects, the techniques described herein relate to a method, wherein softening the outer portion of the sacrificial refill layer material includes bombarding an outer surface of the sacrificial refill layer material with H₂ for approximately 2-3 seconds: using a dilute gas including one or more of He, Ar, or N₂; at a power between approximately 10 W to approximately 4000 W; at a pressure of approximately 1 mT to approximately 100 mT; and with a gas flow of approximately 20 sccm (standard cubic centimeter per minute) to approximately 3000 sccm.

In some aspects, the techniques described herein relate to a method, wherein removing the softened outer portion of the sacrificial refill layer material includes etching the softened outer portion from an outer surface of the sacrificial refill layer material.

In some aspects, the techniques described herein relate to a method, wherein removing the softened outer portion of the sacrificial refill layer material includes etching the softened outer portion from an outer surface of the sacrificial refill layer material: using an etch gas including CHF₃, CF₄, CH₂F₂, or NF₃; using a dilute gas including one or more of He, Ar, or N₂; at a power between approximately 10 W to approximately 4000 W; at a pressure of approximately 1 mT to approximately 800 mT; and with a gas flow of approximately 20 sccm (standard cubic centimeter per minute) to approximately 3000 sccm.

In some aspects, the techniques described herein relate to a semiconductor structure, including: a plurality of vertically spaced nanostructures above a substrate, the plurality of vertically spaced nanostructures including a first nanostructure, a second nanostructure below the first nanostructure, and a third nanostructure below the second nanostructure; source/drain regions on opposite sides of the plurality of vertically spaced nanostructures; and a plurality of metal gate structures above and below the plurality of vertically spaced nanostructures, wherein the plurality of metal gate structures includes a first metal gate structure with a first metal gate width (W1), a second metal gate structure with a second metal gate width (W2) below the first metal gate structure, and a third metal gate structure with a third metal gate width (W3) below the second metal gate structure; wherein a ratio of W1 to W2 is approximately 0.95 to approximately 0.97, a ratio of W1 to W3 is approximately 0.93 to approximately 0.94, a ratio of W2 to W3 is approximately 0.95 to approximately 0.97.

In some aspects, the techniques described herein relate to a semiconductor structure, wherein a difference in height between a middle region of a vertically space nanostructure and an outer region of that vertically spaced nanostructure is less than 1 nm.

In some aspects, the techniques described herein relate to a semiconductor structure, wherein the first nanostructure has a first thickness, the second nanostructure has a second thickness, and the third nanostructure has a third thickness, and wherein the first thickness, the second thickness, and the third thickness are approximately equal to 9 nm to approximately 10 nm.

In some aspects, the techniques described herein relate to a semiconductor structure, wherein the first metal gate structure has a first metal gate thickness, the second metal gate structure has a second metal gate thickness, and the third metal gate structure has a third metal gate thickness, wherein the first metal gate thickness is approximately equal to the second metal gate thickness and the third metal gate thickness.

In some aspects, the techniques described herein relate to a semiconductor structure, wherein the first metal gate thickness, the second metal gate thickness, and the third metal gate thickness are approximately equal to 7 nm to approximately 8 nm.

In some aspects, the techniques described herein relate to a semiconductor structure, wherein the first metal gate width is approximately equal to the second metal gate width, and the second metal gate width is approximately equal to the third metal gate width.

In some aspects, the techniques described herein relate to a semiconductor structure, wherein the first metal gate width, the second metal gate width, and the third metal gate width differ by less than 1 nm.

In some aspects, the techniques described herein relate to a semiconductor structure, wherein a magnitude of the second metal gate width minus a magnitude of the first metal gate width is between 0 to approximately 0.5 nm.

In some aspects, the techniques described herein relate to a semiconductor structure, wherein a magnitude of the third metal gate width minus a magnitude of the second metal gate width is between 0 to approximately 1 nm.

In some aspects, the techniques described herein relate to a semiconductor structure, wherein: a tangent line is defined along an outer sidewall edge of an inner spacer for the first metal gate structure, an inner spacer for the second metal gate structure, and an inner spacer for the third metal gate structure; a first angle is defined between a horizontal line under the third metal gate structure and a location on the tangent line at the third metal gate structure, a second angle is defined between the horizontal line and a location on the tangent line at the second metal gate structure, and a third angle is defined between the horizontal line and a location on the tangent line at the third metal gate structure; the first angle has a magnitude between approximately 90° to approximately 91°; the second angle has a magnitude between approximately 92° to approximately 93°; and the third angle has a magnitude between approximately 94° to approximately 98°.

In some aspects, the techniques described herein relate to a method, including: providing a semiconductor structure including a plurality of vertically spaced channel epitaxial layers and a plurality of vertically spaced sacrificial epitaxial layers positioned between the plurality of vertically spaced channel epitaxial layers, a sacrificial gate structure formed over the semiconductor structure, gate sidewall spacers formed on sidewalls of the sacrificial gate structure, and recessed areas for source and drain regions; removing the plurality of vertically spaced sacrificial epitaxial layers from between the plurality of vertically spaced channel epitaxial layers; depositing sacrificial oxide layer over and around the semiconductor structure; selectively etching the sacrificial oxide layer using a plurality of selective removal sequences until a desired level of the sacrificial oxide layer has been removed, wherein each selective removal sequence includes changing a physical characteristic of an outer portion of the sacrificial oxide layer and removing the changed outer portion of the sacrificial oxide layer; forming an inner spacer layer at sidewalls of the sacrificial oxide layer; forming source/drain features; and replacing the sacrificial gate structure and the sacrificial oxide layer with a plurality of vertically spaced metal gate structures including a first metal gate structure, a second metal gate structure below the first metal gate structure, and a third metal gate structure below the second metal gate structure.

In some aspects, the techniques described herein relate to a method, wherein the first metal gate structure has a first metal gate thickness, the second metal gate structure has a second metal gate thickness, and the third metal gate structure has a third metal gate thickness, wherein the first metal gate thickness is approximately equal to the second metal gate thickness and the third metal gate thickness.

In some aspects, the techniques described herein relate to a method, wherein the first metal gate thickness, the second metal gate thickness, and the third metal gate thickness are approximately equal to 7 nm to approximately 8 nm.

In some aspects, the techniques described herein relate to a method, wherein the first metal gate structure has a first metal gate width, the second metal gate structure has a second metal gate width, and the third metal gate structure has a third metal gate width, wherein the first metal gate width is approximately equal to the second metal gate width, and the second metal gate width is approximately equal to the third metal gate width.

In some aspects, the techniques described herein relate to a method, wherein the first metal gate width, the second metal gate width, and the third metal gate width differ by less than 1 nm.

In some aspects, the techniques described herein relate to a method, wherein a magnitude of the second metal gate width minus a magnitude of the first metal gate width is between 0 to approximately 0.5 nm.

In some aspects, the techniques described herein relate to a method, wherein a magnitude of the third metal gate width minus a magnitude of the second metal gate width is between 0 to approximately 1 nm.

In some aspects, the techniques described herein relate to a method, wherein: a tangent line is defined along an outer sidewall edge of an inner spacer for the first metal gate structure, an inner spacer for the second metal gate structure, and an inner spacer for the third metal gate structure; a first angle is defined between a horizontal line under the third metal gate structure and a location on the tangent line at the third metal gate structure, a second angle is defined between the horizontal line and a location on the tangent line at the second metal gate structure, and a third angle is defined between the horizontal line and a location on the tangent line at the third metal gate structure; the first angle has a magnitude between approximately 90° to approximately 91°; the second angle has a magnitude between approximately 92° to approximately 93°; and the third angle has a magnitude between approximately 94° to approximately 98°.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A method, comprising:
providing a semiconductor structure comprising a plurality of vertically spaced channel structures and a plurality of vertically spaced sacrificial epitaxial layers positioned between the plurality of vertically spaced channel structures, a sacrificial gate structure formed over the semiconductor structure, and gate sidewall spacers formed on sidewalls of the sacrificial gate structure;
recessing the semiconductor structure in source and drain regions;
removing the plurality of vertically spaced sacrificial epitaxial layers from between the plurality of vertically spaced channel structures;
depositing sacrificial refill layer material over and around the semiconductor structure;
selectively etching the sacrificial refill layer material using a selective removal sequence until a desired level of the sacrificial refill layer material has been removed, wherein the selective removal sequence comprises a treatment phase and a removal phase, wherein the treatment phase comprises softening an outer portion of the sacrificial refill layer material and the removal phase comprises removing the softened outer portion of the sacrificial refill layer material;
forming an inner spacer layer at sidewalls of the sacrificial refill layer material;
forming source/drain features; and
replacing the sacrificial gate structure and the sacrificial refill layer material with a metal gate structure.

2. The method of claim 1, wherein the sacrificial refill layer material comprises a silicon oxide compound.

3. The method of claim 1, wherein the sacrificial refill layer material comprises SiO₂, SiOH, SiOC, or SiOCH.

4. The method of claim 1, wherein softening the outer portion of the sacrificial refill layer material comprises bombarding the outer portion with H₂ gas.

5. The method of claim 1, wherein softening the outer portion of the sacrificial refill layer material comprises creating a softened region with a depth of approximately 1 nanometer (nm) to approximately 1.5 nm.

6. The method of claim 1, wherein softening the outer portion of the sacrificial refill layer material comprises bombarding an outer surface of the sacrificial refill layer material with H₂ gas for approximately 2 to 3 seconds:
using a dilute gas comprising one or more of He, Ar, or N₂;
at a power between approximately 10 W to approximately 4000 W;
at a pressure of approximately 1 mT to approximately 100 mT; and
with a gas flow of approximately 20 sccm (standard cubic centimeter per minute) to approximately 3000 sccm.

7. The method of claim 1, wherein removing the softened outer portion of the sacrificial refill layer material comprises etching the softened outer portion from an outer surface of the sacrificial refill layer material:
using an etch gas comprising CHF₃, CF₄, CH₂F₂, or NF₃;
using a dilute gas comprising one or more of He, Ar, or N₂;
at a power between approximately 10 W to approximately 4000 W;
at a pressure of approximately 1 mT to approximately 800 mT; and
with a gas flow of approximately 20 sccm (standard cubic centimeter per minute) to approximately 3000 sccm.

8. A semiconductor structure, comprising:
a plurality of vertically spaced nanostructures above a substrate, the plurality of vertically spaced nanostructures comprising a first nanostructure, a second nanostructure below the first nanostructure, and a third nanostructure below the second nanostructure;
source/drain regions on opposite sides of the plurality of vertically spaced nanostructures; and
a plurality of metal gate structures above and below the plurality of vertically spaced nanostructures, wherein the plurality of metal gate structures comprises a first metal gate structure with a first metal gate width (W1), a second metal gate structure with a second metal gate width (W2) below the first metal gate structure, and a third metal gate structure with a third metal gate width (W3) below the second metal gate structure;
wherein a ratio of W1 to W2 is approximately 0.95 to approximately 0.97, a ratio of W1 to W3 is approximately 0.93 to approximately 0.94, a ratio of W2 to W3 is approximately 0.95 to approximately 0.97.

9. The semiconductor structure of claim 8, wherein a difference in height between a middle region of a vertically space nanostructure and an outer region of that vertically spaced nanostructure is less than 1 nm.

10. The semiconductor structure of claim 8, wherein the first nanostructure has a first thickness, the second nanostructure has a second thickness, and the third nanostructure has a third thickness, and wherein the first thickness, the second thickness, and the third thickness are approximately equal to 9 nm to approximately 10 nm.

11. The semiconductor structure of claim 8, wherein the first metal gate structure has a first metal gate thickness, the second metal gate structure has a second metal gate thickness, and the third metal gate structure has a third metal gate thickness, wherein the first metal gate thickness is approximately equal to the second metal gate thickness and the third metal gate thickness.

12. The semiconductor structure of claim 11, wherein the first metal gate thickness, the second metal gate thickness, and the third metal gate thickness are approximately equal to 7 nm to approximately 8 nm.

13. The semiconductor structure of claim 8, wherein the first metal gate width is approximately equal to the second metal gate width, and the second metal gate width is approximately equal to the third metal gate width.

14. The semiconductor structure of claim 13, wherein the first metal gate width, the second metal gate width, and the third metal gate width differ by less than 1 nm.

15. A method, comprising:
providing a semiconductor structure comprising a plurality of vertically spaced channel epitaxial layers and a plurality of vertically spaced sacrificial epitaxial layers positioned between the plurality of vertically spaced channel epitaxial layers, a sacrificial gate structure formed over the semiconductor structure, gate sidewall spacers formed on sidewalls of the sacrificial gate structure, and recessed areas for source and drain regions;
removing the plurality of vertically spaced sacrificial epitaxial layers from between the plurality of vertically spaced channel epitaxial layers;
depositing sacrificial oxide layer over and around the semiconductor structure;
selectively etching the sacrificial oxide layer using a plurality of selective removal sequences until a desired level of the sacrificial oxide layer has been removed, wherein each selective removal sequence comprises changing a physical characteristic of an outer portion of the sacrificial oxide layer and removing the changed outer portion of the sacrificial oxide layer;
forming an inner spacer layer at sidewalls of the sacrificial oxide layer;
forming source/drain features; and
replacing the sacrificial gate structure and the sacrificial oxide layer with a plurality of vertically spaced metal gate structures comprising a first metal gate structure, a second metal gate structure below the first metal gate structure, and a third metal gate structure below the second metal gate structure.

16. The method of claim 15, wherein the first metal gate structure has a first metal gate thickness, the second metal gate structure has a second metal gate thickness, and the third metal gate structure has a third metal gate thickness, wherein the first metal gate thickness is approximately equal to the second metal gate thickness and the third metal gate thickness.

17. The method of claim 15, wherein the first metal gate structure has a first metal gate width, the second metal gate structure has a second metal gate width, and the third metal gate structure has a third metal gate width, wherein the first metal gate width is approximately equal to the second metal gate width, and the second metal gate width is approximately equal to the third metal gate width.

18. The method of claim 17, wherein a magnitude of the second metal gate width minus a magnitude of the first metal gate width is between 0 to approximately 0.5 nm.

19. The method of claim 17, wherein a magnitude of the third metal gate width minus a magnitude of the second metal gate width is between 0 to approximately 1 nm.

20. The method of claim 15, wherein:
a tangent line is defined along an outer sidewall edge of an inner spacer for the first metal gate structure, an inner spacer for the second metal gate structure, and an inner spacer for the third metal gate structure;
a first angle is defined between a horizontal line under the third metal gate structure and a location on the tangent line at the third metal gate structure, a second angle is defined between the horizontal line and a location on the tangent line at the second metal gate structure, and a third angle is defined between the horizontal line and a location on the tangent line at the third metal gate structure;
the first angle has a magnitude between approximately 90° to approximately 91°;
the second angle has a magnitude between approximately 92° to approximately 93°; and
the third angle has a magnitude between approximately 94° to approximately 98°.
